(19) United States
(12) Patent Application Publication
(10) Pub. No.: US 2012/0193433 A1
(43) Pub. Date: Aug. 2, 2012

(54) ELECTROMAGNETIC IDENTIFICATION (EMID) SECURITY TAG

(76) Inventors: John Chao Chang, Saratoga, CA (US); Wen Xin Bai, ChangZhou (CN)

(21) Appl. No.: 13/018,042

(22) Filed: Jan. 31, 2011

(51) Int. Cl. G06K 19/077; H05K 13/00

(52) U.S. Cl. 235/492; 29/592.1

(57) ABSTRACT

A method of manufacturing a surveillance article has the step of providing a first security element comprising an electromagnetic strip. The first security element provides a first functionality of the surveillance article. The method then connects a second security element to the electromagnetic strip and the second security element provides a second functionality that is different than the first functionality. The second security element comprises a radiofrequency identification device to provide the surveillance article.

### FIELD OF THE INVENTION

The present disclosure is directed to a multifunctional security tag. More particularly, the present disclosure is directed to a tag that has one element for a first tracking functionality and a second different element for a second tracking functionality.

### BACKGROUND OF THE RELATED ART

Electronic surveillance articles are known in the art. Some electronic surveillance articles exhibit very high detection sensitivity. These electronic surveillance articles function aptly in providing theft security. However, some electronic surveillance articles are not capable of information storage for the purposes of product tracking, identification, data collection, and inventory control.

UHF RFID radiofrequency tags are also known in the art. UHF RFID tags incorporate storage chips, which can store substantial information and can be read from distances of 4 to 10 feet, but can be easily shielded with metal and liquid materials. This renders the electronic surveillance articles undetectable and thus useless for security purposes.

### SUMMARY OF THE INVENTION

An electromagnetic radiofrequency identification tag, which is a combination of two or more elements, (or devices) exhibits both high sensitivity that cannot be easily neutralized by shielding. The present disclosure also has the advantage of RFID tags or long distance readability and a data storage capability.

According to a first aspect of the present disclosure, there is provided a security tag comprising a first substrate and a first security element being disposed on the first substrate. The first security element provides a first functionality of the security tag. The security tag also has a second security element disposed on the first substrate. The second security element provides a second functionality that is different than the first functionality.

In yet another aspect of the present disclosure there is provided a security tag comprising a first security element. The first security element comprises an electromagnetic strip. The first security element provides a first functionality of the security tag.

The security tag also has a second security element arranged with the electromagnetic strip. The second security element provides a second functionality different than the first functionality. The second security element comprises a radiofrequency identification device. The electromagnetic strip has a width that is complementary to the radiofrequency identification device.

In another embodiment of the present disclosure, there is provided a method of manufacturing a surveillance article. The method has the step of providing a first security element comprising an electromagnetic strip. The first security element provides a first functionality of the surveillance article. The method then connects a second security element to the electromagnetic strip and the second security element provides a second functionality that is different than the first functionality. The second security element comprises a radiofrequency identification device to provide the completed surveillance article.

### BRIEF DESCRIPTION OF THE FIGURES

The foregoing and other objects, features and advantages of the invention will be apparent from the following more particular description of preferred embodiments of the invention, as illustrated in the accompanying drawings in which like reference characters refer to the same parts throughout different views. The drawings are not meant to limit the invention to particular mechanisms for carrying out the invention in practice, but rather, the drawings are illustrative of certain ways of performing the invention. Others will be readily apparent to those skilled in the art.

FIG. 1 shows a number of first security devices or elements.

FIG. 2 shows a second security device or element being removed from a carrier.

FIG. 3 shows a first embodiment of the security tag according to the present disclosure.

FIG. 4 shows a second embodiment of the security tag of FIG. 3.

FIG. 5 shows another embodiment of the security tag of the present disclosure.

FIGS. 6-7 show yet other embodiments of the security tag of the present disclosure.

FIG. 8 shows a number of method steps to manufacture the security tag; and

FIG. 9 shows a side view of the security tag of the present disclosure.

### DETAILED DESCRIPTION OF THE PREFERRED EMBODIMENTS

The present disclosure preferably is directed to an electronic surveillance article or tag 18 that is multifunctional. Preferably, the electronic surveillance article 18 comprises at least two different devices or elements that provide at least two different functional advantages. In another embodiment, the electronic surveillance article or tag 18 may comprise two or more different devices to provide two or more functional advantages. In one embodiment, the electronic surveillance article or tag 18 comprises a first security device or an electromagnetic security strip and a second different security device.

The second security device can be a 900 MHz integrated circuit chip (Radio-frequency identification, or RFID chip). By combining the first and the second security devices, the tag 10 forms an electromagnetic identification tag (EMID tag) that is multifunctional. The tag 10 in one embodiment can serve the combined functions of both types of tags and product tracking, product identification, product data collection, and inventory control with highly sensitive detection performance and low cost.

The present tag 18 also provides qualities and performance of both UHF RFID tags and EM strips in a single product. The tag 18 also provides robust detection performance near any materials, including metals and liquids, fast read speeds and reliable read rates of over 99.99%, long reading range of greater than about 3.5 meters and the tag 18 is compatible with all EM detection gates and UHF RFID readers, which is advantageous. The tag 18 further is capable of data storage and may include a 240+ bit EPC global Class 1 Gen2-compliant silicon chip as the second security device.

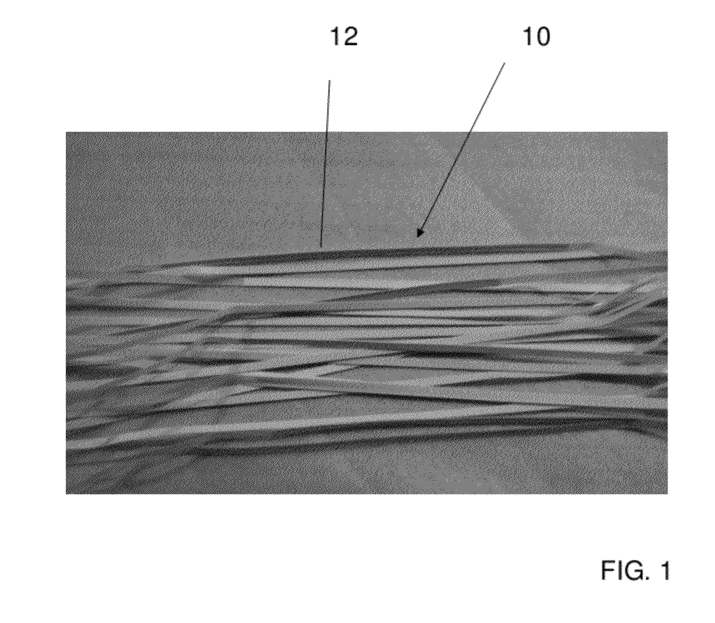

Turning now to FIG. 1, there is shown a perspective view of a number of electromagnetic strips 10 being connected a backing paper 12 as an adhesive or the like. In one embodiment, the first security device or element can be an electromagnetic strip 10, however, this arrangement is not limiting. Preferably, the electromagnetic strip 10 is a removable member that is low cost and is manufactured as a strip of amorphous metal (metglas) which has a very low magnetic saturation value.

The electromagnetic strip 10 is also lined with a strip of ferromagnetic material with a moderate coercive field (magnetic “hardness”). The electromagnetic strip 10 is well known in the art and common place. Detection of the electromagnetic strip 10 is achieved by sensing harmonics of the electromagnetic strip 10. A sum or a difference signal being generated by the non-linear magnetic response of the electromagnetic strip 10 is monitored under a mixture of low-frequency (in the 10 Hz to 1000 Hz range) magnetic fields. In another embodiment, the first security device 10 can be a different security device and can be any type of electronic article surveillance system including a magnetic electronic article surveillance tag, a magneto-harmonic tag, an acoustic-magnetic tag, a magnetostrictive tag, a radio frequency tag, a microwave tag or any other tag known in the art. Preferably, the strip 10 is connected to a backing paper 12 by an adhesive, but may also be connected via a different connector.

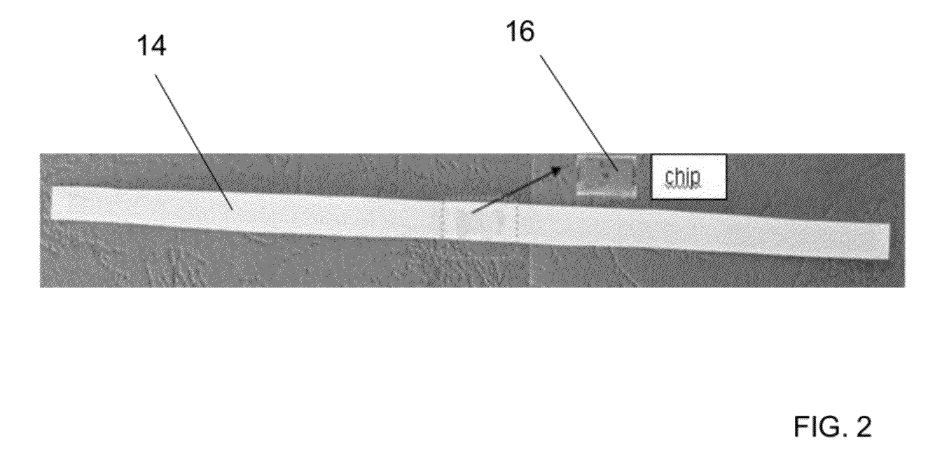

Turning now to FIG. 2, there is shown the second security device 16 being removed from a substrate 14. In this embodiment, the second security device 16 is a different type of device that the first device 10 discussed above and that provides a different functionality relative to the first device 10. The second security device 16 is a radiofrequency device. In one non-limiting embodiment, the second security device 16 is a 915 MHz RFID tag 16. Preferably, the second security device 16 was purchased and the RFID chip 16 was removed from the center of the substrate 14 as shown. Preferably, the second security device 16 is a Radio-frequency identification (RFID). The second element or RFID 16 uses communication via radio waves. This is to exchange data between a reader and an electronic tag, which is attached to an object for the purpose of identification and tracking. The second security device 16 preferably is operable with Radio-frequency identification and involves interrogators (also known as Radio-frequency readers). The second security device 16 is preferably connected to the device 10 by an adhesive or the like; however, it may be connected via other methods. Preferably, there is no cap between the EM strip 10 (16 cm) and the RFID strip 16 (10 cm length strip with 1.0 cm×2.5 cm opening in the center). Preferably, the RFID strip 16 is to function as the RF antenna as well. The EM strip component 10 is connected the RFID tag component 16 in a side by side manner and in parallel by adhesive glue paper.

The second security device 16 preferably has at least two parts. One is an integrated circuit for storing and processing information, modulating and demodulating a radio-frequency (RF) signal, and other specialized functions. The other is an antenna for receiving and transmitting the signal. The second security device 16 can be a passive tag, an active tag or can be an assisted battery tag that further comprises a battery or the like. A second security device 16 passive RFID tag has no power source.

The second security device 16 passive RFID tag requires an external electromagnetic field to initiate a signal transmission. Second security device 16 active RFID tag has a battery and can transmit signals once an external source or the Interrogator has been successfully identified. Second security device 16 battery assisted passive (BAP) RFID tag require an external source to be activated, however may further have a higher forward link capability and greater range. There are a variety of groups defining standards and regulating the use of RFID for the second security device 16, including the International Organization for Standardization (ISO), the International Electrotechnical Commission (IEC), ASTM International, the DASH7 Alliance and EPCglobal, which are all incorporated by reference in their entirety. Preferably, the second security device 16 can be utilized in enterprise supply chain management to improve the efficiency of inventory tracking and management.

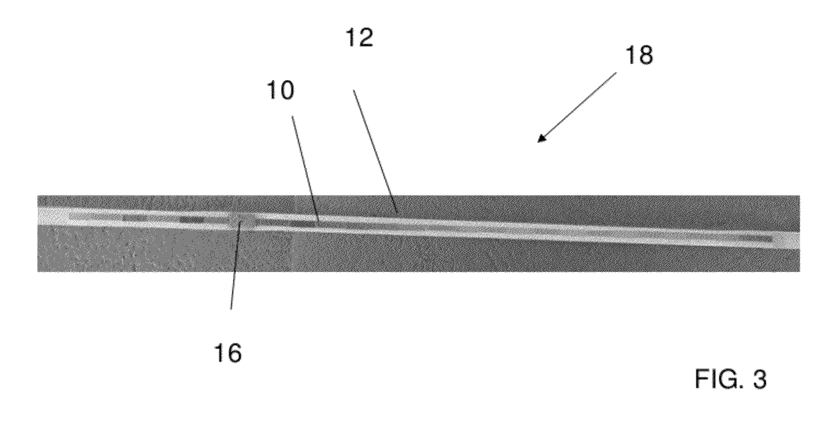

Turning now to FIG. 3, there is shown the first security device 10 being connected to the second security device 16. Here, the removed RFID device 16 was simply attached onto an EM security strip 10, composing the first EMID security tag generally shown as reference numeral 18. During the testing period for the security tag 18, it was discovered that while the performance of the first security device 10 was relatively stable (charging and degaussing effects were very good), the reading sensitivity of the second security device 16 was not acceptable, fluctuating between performance levels.

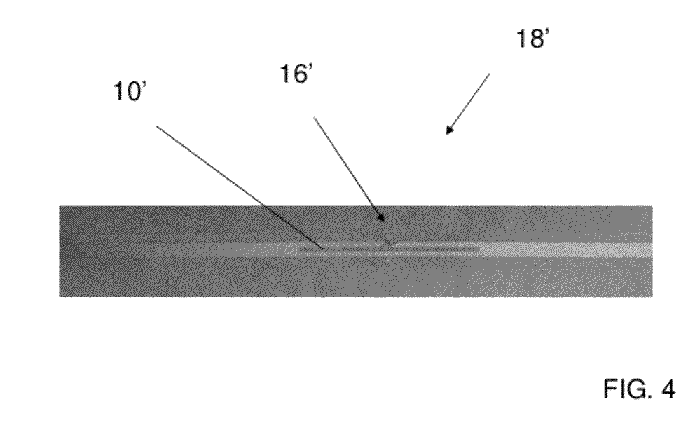

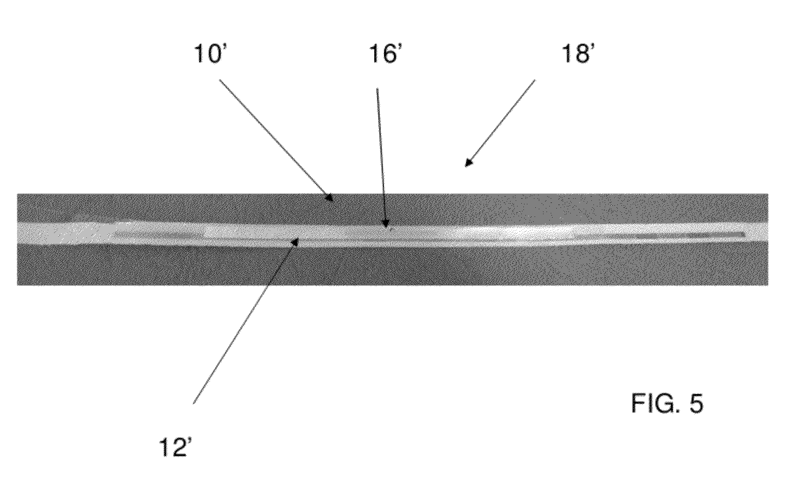

Turning now to FIG. 4, there is shown an alternative embodiment of the present disclosure of a security tag 18′. Turning now to FIG. 5, there is shown an alternative embodiment of the present disclosure. The security tag 18′ comprises connecting the RFID tag or the second device 16′ onto the EM strip backing paper 12′, beside, rather than directly on top of the first security device 10′ or the EM strips 10′. After testing the security tag 18′, it was discovered that while the performance of the first security device 10′ (EM tag component 10′) remained relatively stable, the reading sensitivity of the second security device 16′ (RF chip component 16′) fluctuated. The weak performance of the second security device 16′ (RF chip component 16′) was identified to be caused by masking of second security device 16′ (RF chip component 16′) by the bulk of the security device 10′ (EM tag component 10′), which were considerably thicker in width.

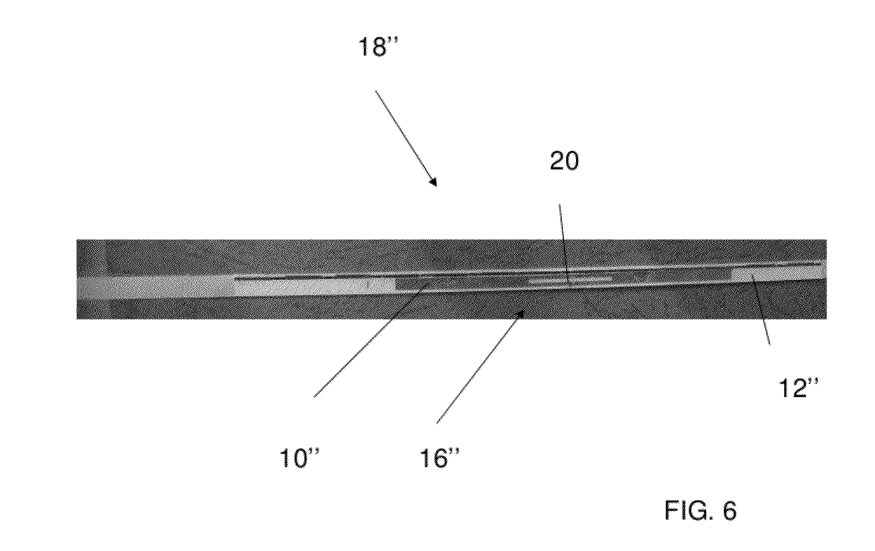

Turning now to FIG. 6, there is shown an alternative embodiment of the security tag 18″ having the first security device 10″ and the second security device 16″. In order to reduce shielding of the second security device 16″ (RF chip component 16″) by the first security device 10″ (EM tag component 10″), a developed narrower EM strip 10″ of the same width as the RFID tag 16″ was used in construction. The developed narrower EM strip 10″ is preferably cut or trimmed to match a length to the element 16″. In one embodiment, the EM strip 10″ is cut lengthwise to match the length of the element 16″. In another embodiment, the EM strip 10″ is cut widthwise to match the width of the element 16″. In yet a further embodiment, the EM strip 10″ is cut depth wise to match the depth of the element 16″. In another embodiment, two or more parameters are altered to match the element 16″. In one embodiment, the preferred EM strip 10 is 16 cm in length and RF chip component 16 is 10 cm in length. However, these lengths may vary and be any lengths known in the art.

The security tag 18″ was constructed by connecting the RFID tag 16″ to a conductor 20. The conductor 20 is preferably a number of strips of metal 20. The conductor 20 is intended to act as a sensitivity amplifying antennae. The conductor 20 was then connected to the backing paper 12″ of the newly developed narrower EM strip 10″. The embodiment of the security tag 18″ was then tested. The security tag 18″ revealed that performance of the EM strip component 10″ remained unchanged, and the performance of RFID tag component 16″ showed improvement in the quality and stability of data reading, but only at short distances from RF readers. Other conductors 20 are also possible and envisioned.

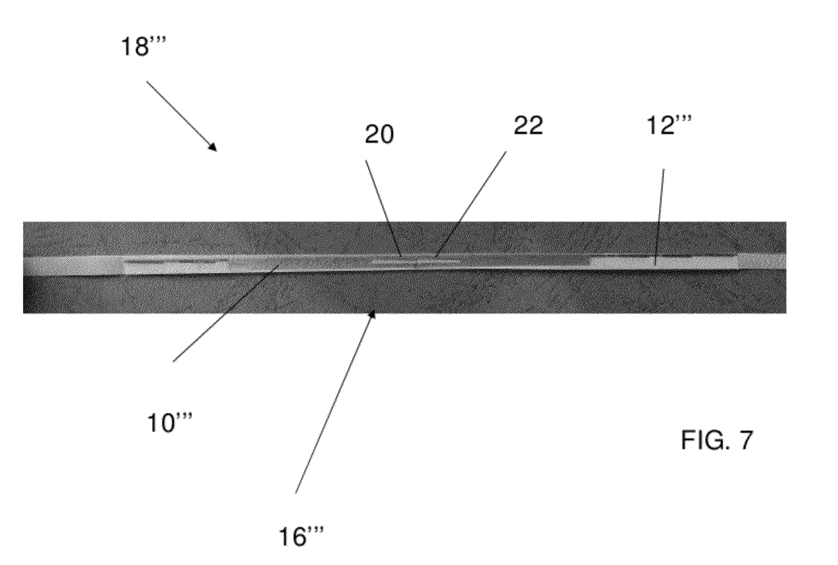

Turning now to FIG. 7, there is shown another embodiment of the security tag 16″. The EM strip component 16′″ was connected the RFID tag component 10′″ side by side by adhesive glue paper. Since the RFID tag component 10′″ functions as an antenna for the RFID reader, cut a rectangular open space in the center of RFID tag component 10′″. The space created can be any size and shape. This ensures that the signals of RF and EM tags were not blocked or shielded. The test results of the security tag 16′″ showed that the performance of EM security tag 16′″ and the RFID tag component 10′″ remained very stable. The RF data sensing and reading capability of the prototype was also shown to be very stable. The RFID component 10′″ reliably exhibited higher sensitivity at high distances. Thus, the security device 16′″ was determined to have met the standard requirements for library applications.

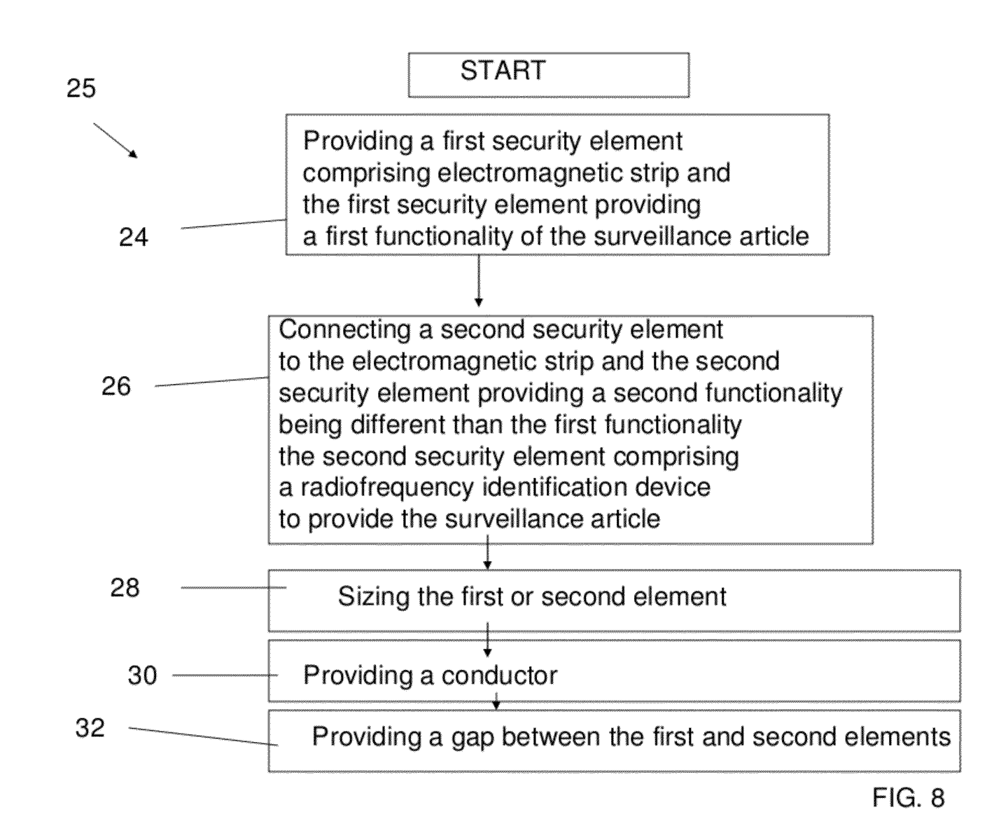

Turning now to FIG. 8, there is shown a method generally shown as reference numeral 25. The method commences and the passes to step 24. At step 24, the method 25 provides a first security element that provides a first functionality to the security tag 18. The first security element may be various electronic articles as previously described. The method 25 then passes to step 26 where a second security element is provided that provides a second functionality to the security tag 18 that is different than the first functionality. In one embodiment, an RFID device is selected. The method 25 then passes to step 28. At step 28, the devices selected above are sized to have a width that is complementary to one another. In another embodiment, the length is complementary. In another embodiment other dimensions are complementary to one another. Control then passes to step 30 where a conductor 20 is provided. At step 32, spacing between the devices is also selected. Thereafter, the method 25 ends.

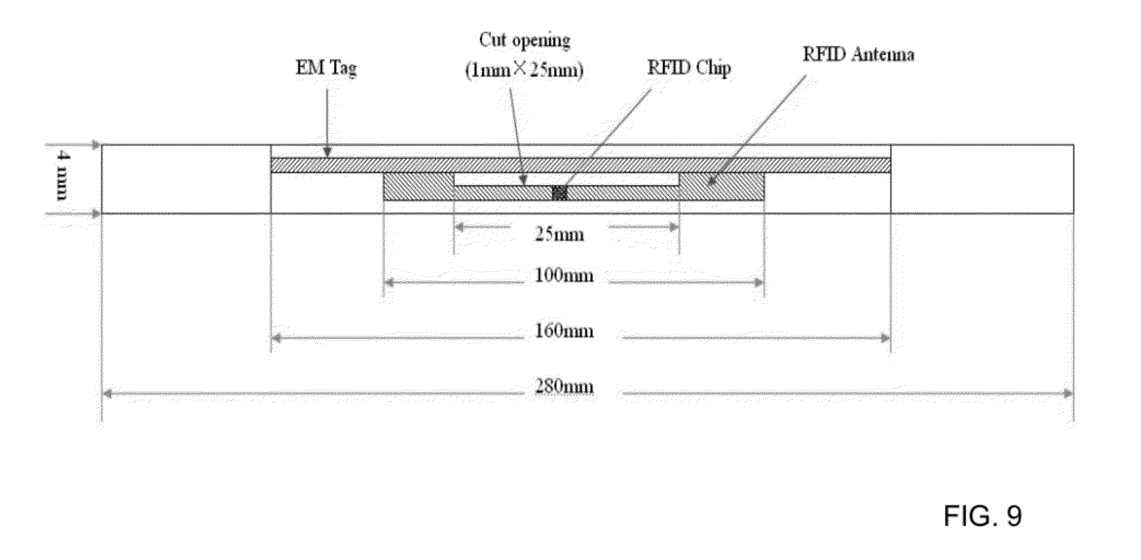

Turning now to FIG. 9, there is shown a side view of the security tag 18. The tag 18 comprises the first security device 10 and the second security device 16. The tag 18 also has a conductor 20 forming an antenna and a gap or space 22. Preferably, the first security device is an electromagnetic strip 10 and is 16 cm in length. Preferably, the second security device 16 is an RFID device 16 being 2.5 cm in length and having the conductor 20 forming the antenna, which is 10 cm in length. Further, the cut opening or gap 22 is 1 by 2.5 cm as shown. It should be appreciated that various lengths and dimensions may be used and the above is merely illustrative of one embodiment of the present disclosure.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof.

Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

Changes can be made to the invention in light of the above Detailed Description. While the above description describes certain embodiments of the invention, and describes the best mode contemplated, no matter how detailed the above appears in text, the invention can be practiced in many ways. Details of the compensation system described above may vary considerably in its implementation details, while still being encompassed by the invention disclosed herein.

As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

All of the above patents and applications and other references, including any that may be listed in accompanying filing papers, are incorporated herein by reference. Aspects of the invention can be modified, if necessary, to employ the systems, functions, and concepts of the various references described above to provide yet further embodiments of the invention.

While this invention has been particularly shown and described with references to a preferred embodiment thereof, it will be understood by those skilled in the art that is made therein without departing from the spirit and scope of the invention as defined by the following claims.

What is claimed is:

1. A security tag comprising:
a first substrate;
a first security element being disposed on the first substrate, the first security element providing a first functionality of the security tag; and
a second security element being disposed on the first substrate, the second security element providing a second functionality being different than the first functionality.

2. The security tag of claim 1, wherein the first security element comprises an electromagnetic security strip.

3. The security tag of claim 1, wherein the second security element comprises an integrated circuit.

4. The security tag of claim 3, wherein the integrated circuit comprises a radiofrequency identification device.

5. The security tag of claim 4, wherein the radiofrequency identification device comprises a 900 MHz integrated circuit radiofrequency identification chip.

6. The security tag of claim 4, wherein the radiofrequency identification device comprises a UHF RFID tag that has a memory that stores at least 240 bits of data.

7. The security tag of claim 1, wherein the first substrate comprises a backing paper, and wherein the second security element is connected to the backing paper.

8. The security tag of claim 1, wherein the first security element has a width that is the same as a width of the second security element.

9. The security tag of claim 8, wherein the second security element is connected to a conductor.

10. The security tag of claim 9, wherein the second security element is a radiofrequency identification device, and wherein the second security element is connected to the conductor.

11. The security tag of claim 10, wherein the conductor is metal.

12. The security tag of claim 11, wherein the radiofrequency identification device is connected to a plurality of strips of metal.

13. The security tag of claim 9, wherein the conductor acts as a sensitivity amplifying antennae.

14. The security tag of claim 13, further comprising adhering the conductor to the substrate.

15. The security tag of claim 9, further comprising adhering the conductor to a backing paper of the first security element.

16. The security tag of claim 15, wherein the first security element is an electromagnetic strip.

17. The security tag of claim 1, further comprising providing a gap between the first and second security elements.

18. A security tag comprising:
a first security element comprising electromagnetic strip, the first security element providing a first functionality of the security tag; and
a second security element arranged with the electromagnetic strip, the second security element providing a second functionality being different than the first functionality, the second security element comprising a radiofrequency identification device, wherein the electromagnetic strip has a width that is complementary to the radiofrequency identification device.

19. The security tag of claim 18, further comprising a conductor.

20. The security tag of claim 19, further comprising a gap being disposed between the first and second security devices.

21. The security tag of claim 20, further comprising a backing paper, wherein the backing paper supports at least one of the conductor, the first security device or the second security device.

22. The security tag of claim 21, wherein the conductor is a strip of metal, and wherein the widths are the same.

23. A method of manufacturing a surveillance article comprising:
providing a first security element comprising an electromagnetic strip, the first security element providing a first functionality of the surveillance article;
connecting a second security element to the electromagnetic strip, the second security element providing a second functionality being different than the first functionality, the second security element comprising a radiofrequency identification device to provide the surveillance article.

24. The method of claim 23, further comprising trimming at least one of the first or the second security element so the electromagnetic strip has a width that is complementary to a width the radiofrequency identification device.

25. The method of claim 24, further comprising connecting a conductor to the surveillance article to provide a sensitivity amplifying antennae, and wherein the widths of the first and second security elements are substantially the same.
